(19) United States
(12) Patent Application Publication
(10) Pub. No.: US 2025/0293219 A1
(43) Pub. Date: Sep. 18, 2025

(54) SEMICONDUCTOR POWER DEVICE WITH EMBEDDED CURRENT SENSOR BASED ON MAGNETIC FIELD

(71) Applicant: STMicroelectronics International N.V., Geneva (CH)

(72) Inventors: Davide Giuseppe PATTI, Mascalucia (IT); Sandro DALLE FESTE, Novara (IT)

(73) Assignee: STMicroelectronics International N.V., Geneva (CH)

(21) Appl. No.: 19/069,862

(22) Filed: Mar. 4, 2025

(30) Foreign Application Priority Data
Mar. 14, 2024 (IT) 102024000005713

(51) Int. Cl. H01L 25/16; G01R 15/20; G01R 19/00; H01L 23/00; H01L 23/495; H10D 80/20; H10D 80/30

(52) U.S. Cl. CPC H01L 25/16; G01R 15/205; G01R 15/207; G01R 19/0092; H01L 23/49562; H01L 23/49575; H01L 24/48; H10D 80/251; H01L 24/08; H01L 24/49; H01L 2224/08145; H01L 2224/48091; H01L 2224/48145; H01L 2224/48247; H01L 2224/49175; H01L 2924/13091; H01L 2924/1433; H10D 80/30

(57) ABSTRACT

A semiconductor power device is described, having: a package; a power die arranged within the package and integrating a power structure that generates a load electric current designed to be supplied to an electric load. The device is also provided, within the package, with: at least a first conductive path designed to be flown through by a first sensing current, which is a function of the load electric current; and a current sensor with magnetic-based operation, integrated into a sensor die coupled to the first conductive path and which generates a current sensing signal on the basis of the first sensing current and indicative of the load electric current.

### BACKGROUND

### Technical Field

The present solution relates to a semiconductor power device, having a current sensor embedded in a corresponding chip or package, for electric current monitoring based on magnetic field.

### Description of the Related Art

It is known that in electronic devices or systems, in particular for analog power applications, there is a need to implement monitoring of an electric current supplied to a load, in order to control and improve operation of the same electronic devices or systems.

Known solutions for monitoring electric current envisage, for example: using resistors connected in series with the load and monitoring the voltage across the same resistors; or forming current mirrors, using at least two power devices (for example MOSFET transistors) with different areas and different on-state resistances RDSₒₙ, connected in parallel and driven with a same signal.

Other known solutions envisage using Hall-effect sensors, arranged in proximity to the path (for example formed by electric wire or conductive track), which carries the electric current towards the load.

Although allowing implementation of electric current monitoring, the aforementioned known solutions have some drawbacks, for example in terms of area occupation or limitations in the operating frequency, which may be disadvantageous, at least for certain applications.

### BRIEF SUMMARY

The present disclosure is directed to a semiconductor power device that includes a package and a power die arranged within the package. An integrating a power structure is configured to generate a load electric current (Iload) designed configured to be supplied to an electric load. At least a first conductive path is configured to have be flown through by a first sensing current pass therethrough (Ir1), wherein the first sensing current which is a function of said load electric current (Iload). A current sensor with magnetic-based operation, integrated into a sensor die coupled to said first conductive path and configured to generate a current sensing signal (Si), based on said first sensing current (Ir1).

### BRIEF DESCRIPTION OF THE SEVERAL VIEWS OF THE DRAWINGS

For a better understanding of the present disclosure, a preferred embodiment thereof is now described, purely by way of non-limiting example and with reference to the attached drawings, wherein:

FIG. 1 shows a schematic plan view of an electronic power device according to an embodiment of the present solution;

FIG. 2A is a schematic cross-section of the device of FIG. 1, taken along line A-A;

FIG. 2B is a schematic cross-section of the device of FIG. 1, taken along line B-B;

FIG. 2C is a schematic cross-section of the device of FIG. 1, taken along line C-C;

FIG. 3 shows a schematic cross-section of a possible implementation of a power die in the device of FIG. 1; and

FIG. 4 shows a schematic circuit block diagram of the device of FIG. 1.

### DETAILED DESCRIPTION

As used herein, the terms “in contact,” “connected,” and “coupled” are intended to have the broadest possible meaning. For example, the phrase “A is connected to B” should be understood to encompass both a direct connection between A and B, where no intervening components or elements exist, as well as an indirect connection, where one or more intervening components or elements are present between A and B. Similarly, the term “coupled” should be construed in the same manner, such that “A is coupled to B” includes both a direct physical or electrical coupling and an indirect coupling through one or more intermediate components or elements. Unless expressly stated otherwise, these terms do not require direct physical contact.

As will be described below, one aspect of the present solution envisages providing a semiconductor power device having, embedded or integrated within a corresponding container or package, a current sensor with magnetic-based operation, for monitoring an electric current flowing through the same device to be supplied to a load.

As will be described in detail, at least one specific electrical path is defined within the package of the semiconductor power device, designed for a sensing current, which is a function of a load current supplied to the electric load. The magnetic sensor, within the package, is arranged so as to sense a magnetic field generated by the flow of the sensing current along the specific electrical path and provide a sensing signal indicative of the sensing current (and, therefore, based on a proportionality ratio, indicative of the load current).

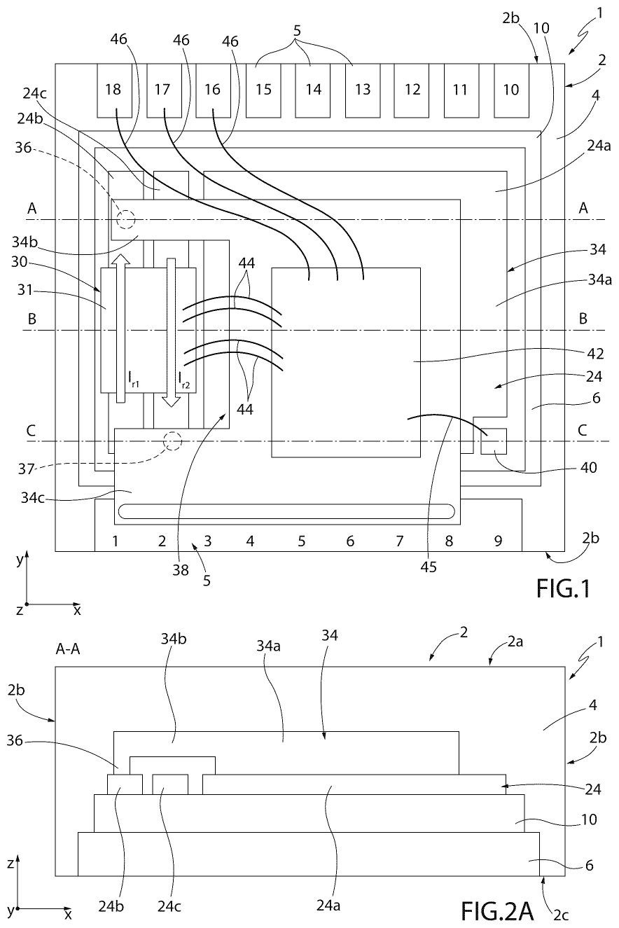

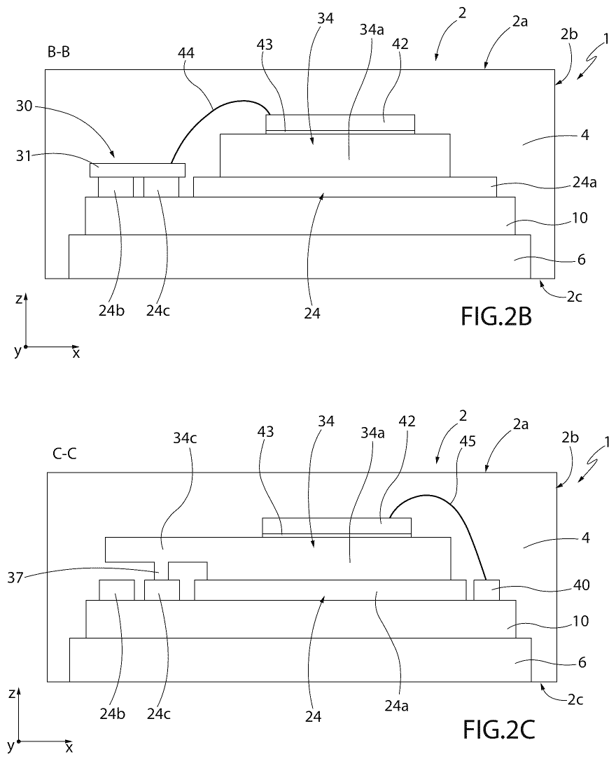

In detail and referring to a possible embodiment shown in FIG. 1 and in the corresponding cross-sections of FIGS. 2A-2C, the semiconductor power device, indicated as a whole by 1, is formed in an integrated manner as a chip and comprises a package 2.

In the example, this package 2 is of the so-called QFN (Quad-Flat No-leads) type having a substantially parallelepiped shape; however, it is emphasized that other types of packages (and other shapes) may likewise be envisaged.

The package 2 comprises an external coating 4, of epoxy resin or other type of material (for example ceramic material), which defines an interface with respect to an external environment and encloses and incorporates therein structural elements which are part of the power device 1.

In particular, the external coating 4 defines an upper external surface 2a and lateral external surfaces 2b of the package 2 and at least part of a corresponding lower external surface 2c. The aforementioned upper and lower external surfaces 2a, 2c have a main extension in a horizontal plane xy and are opposite to each other with respect to a vertical axis z, orthogonal to the horizontal plane xy (a thickness of the package 2 being defined along this vertical axis z).

The package 2 further comprises leads or electrical contact terminals 5, of conductive material, for example copper, possibly coated with a thin layer of nickel, arranged externally with respect to the coating 4 and accessible from the outside (for example being level with the same coating 4), in particular at the lateral external surface 2b of the package 2 and at the lower external surface 2c of the same package 2, intended to be coupled to a Printed Circuit Board (PCB) of an external electronic system wherein the power device 1 is used. An electric load, which, during operation, is supplied with a load electric current flowing and being generated in the power device 1, may also be coupled to the same printed circuit board.

In the illustrated embodiment, the aforementioned electrical contact terminals 5 are arranged in two parallel rows, at opposite faces (along a horizontal axis y) of the lateral external surface 2b of the package 2. In particular, in the example, the electrical contact terminals 5 of each row are nine in number (therefore being indicated with progressive numbers from 1 to 9 for a first row and from 10 to 18 for a second row) aligned along a horizontal axis x, which forms, with the aforementioned horizontal axis y, the horizontal plane xy.

The package 2 internally comprises, incorporated at least in part within the coating 4, a supporting element or frame 6 (commonly referred to as a “leadframe”), made of conductive material, for example copper. In particular, the supporting element 6 defines an isle (or pad), having in the example a substantially rectangular shape, with main extension in the horizontal plane xy and having a lower surface contributing to defining the aforementioned lower external surface 2c of the package 2.

The power device 1 further comprises, within the package 2 and carried by the supporting element 6 on a corresponding upper surface (opposite to the aforementioned lower surface), a power die 10, of semiconductor material, with an integrated power structure configured to generate the aforementioned load electric current. In one embodiment, this integrated power structure is of the MOSFET (Metal Oxide Semiconductor Field Effect Transistor) type.

In a known manner, this integrated power structure comprises a plurality of active cells, contributing to the aforementioned load electric current provided on at least one corresponding current conduction terminal (for example, between drain and source terminals, in the case of a MOSFET structure).

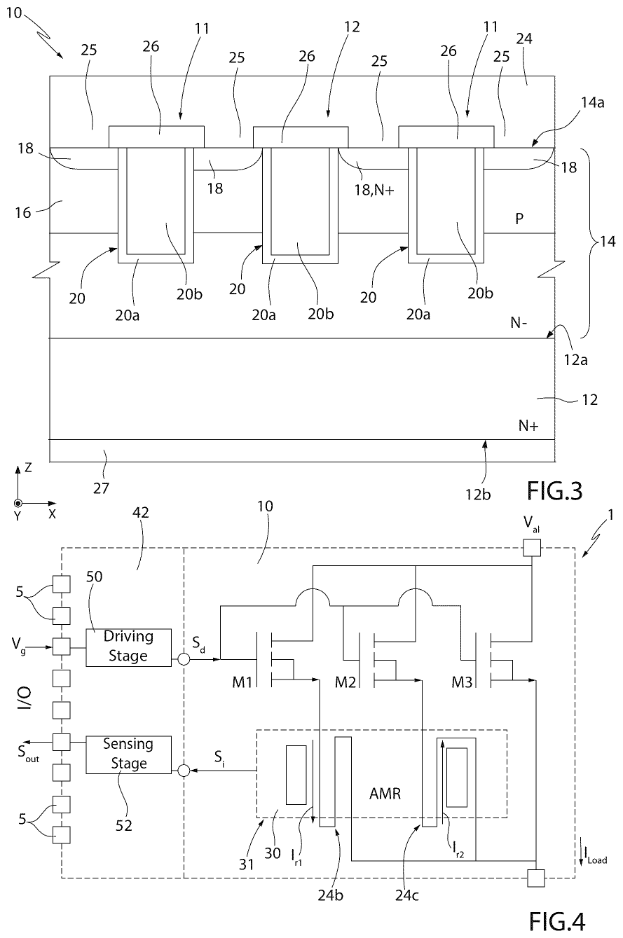

For illustrative (and non-limiting) purposes, FIG. 3 illustrates a schematic cross-section of a possible implementation of the integrated power structure in the power die 10 and the corresponding active cells, indicated here by 11, with reference to a MOSFET structure.

In this implementation, the power die 10 comprises a substrate 12, of doped semiconductor material, for example of N⁺-doped silicon (or, alternatively, of other material, such as for example silicon carbide, SiC). The substrate 12 has a first and a second surface 12a, 12b, opposite to each other along a vertical axis z, orthogonal to the aforementioned horizontal plane xy.

A structural layer 14 of doped semiconductor material, for example of N-doped silicon, is arranged on the first surface 12a of the substrate 12. The structural layer 14 is, for example, grown epitaxially on the substrate 12 and is delimited at the top by an upper surface 14a (opposite to the aforementioned first surface 12a along the vertical axis z).

The structural layer 14 accommodates, at an active area 2, a body region 16, in the example P-doped, extending in depth into the structural layer 14 starting from the upper surface 14a. Source regions 18, in the example N⁺-doped, are arranged within the body region 16, facing the upper surface 14a of the structural layer 14.

The power die 10 further comprises gate regions 20, in the example trench gate regions, formed in respective trenches extending into the structural layer 14 starting from the upper surface 14a towards the substrate 12. Each gate region 20 comprises an external insulating portion 20a (for example, of silicon oxide) and an internal conductive portion 20b (for example, of polysilicon), mutually arranged in such a way that the conductive portion 20b is insulated from the structural layer 4 by the insulating portion 20a.

The power die 10 further comprises, at the active area, a conductive layer, in particular a source metallization 24, formed by a conductive layer, for example a metal layer, which extends on the upper surface 14a of the structural layer 14, in direct contact with the source regions 18, to allow their biasing during operation (thereby forming a source contact terminal, i.e., a first current conduction terminal of the MOSFET structure). The source metallization 24 has a planar extension substantially corresponding to the extension of the active area in the horizontal plane xy.

The source metallization 24 contacts the source regions 18 through a plurality of contact elements 25, which extend into respective contact openings formed through an insulating layer 26, for example of silicon oxide, which covers the upper surface 14a of the structural layer 14 (and in particular insulates the source metallization 24 from the conductive portions 20b of the gate regions 20, which face the same upper surface 14a of the structural layer 14).

In a manner not illustrated here, suitable connection elements are also envisaged above the upper surface 14a of the structural layer 14, for the electrical connection of the gate regions 20 and the definition of a gate contact terminal of the MOSFET structure).

A further conductive layer 27, which forms a drain contact terminal (i.e., a second current conduction terminal of the MOSFET structure), extends on the second surface 12b of the substrate 12, in direct electrical contact with the same substrate 12.

In particular and referring again to what has been illustrated in the aforementioned FIG. 1 and in the corresponding cross-sections of FIGS. 2A-2C, this conductive layer 27 is in direct electrical contact with the supporting element 6 of the power device 1.

According to one aspect of the present solution and as shown in the same FIG. 1 and in the aforementioned cross-sections of FIGS. 2A-2C, the source metallization 24, arranged at the top of the power die 10, comprises a main portion 24a, with extension (for example rectangular or square in the horizontal plane xy) above a large part of the active area and which contacts the majority of the aforementioned source regions 18 of the active cells 11 of the MOSFET transistor. For example, the extension of this main portion 24a is comprised between 50% and 80% of the extension of the aforementioned active area.

Furthermore, the same source metallization 24 comprises at least a first conductive strip 24b, separate and distinct with respect to the aforementioned main portion 24a, with extension, in the example, along the horizontal axis y. In particular, this first conductive strip 24b is arranged at a peripheral portion of the aforementioned active area, laterally with respect to the main portion 24a, above at least one of the aforementioned source regions 18 of a respective one of the active cells 11 (which the same first conductive strip 24b contacts electrically).

The source metallization 24 also preferably comprises a second conductive strip 24c, separate and distinct with respect to the aforementioned main portion 24a and the first conductive strip 24b, with an extension, in the example, along the horizontal axis y, parallel to the same first conductive strip 24b.

In particular, the second conductive strip 24c is interposed between the first conductive strip 24b and the main portion 24a along the horizontal axis x, a certain separation distance being present along the same horizontal axis x between the first and the second conductive strips 24b, 24c and between the same second conductive strip 24c and the main portion 24a.

As shown in FIG. 1 and also in the cross-section of FIG. 2B, the power device 1 further comprises a current sensor 30, with magnetic-based operation, in particular a magnetometer, more in particular based on the principle of magnetoresistance. This current sensor 30 may be an AMR (Anisotropic Magneto Resistance) sensor; alternatively, this current sensor 30 may be a TMR (Tunnel Magneto Resistance) or GMR (Giant Magneto Resistance) sensor.

The current sensor 30 is formed in a sensor die 31, for example of a semiconductor material (such as silicon), which integrates a suitable magnetic field sensing structure, for example of the capacitive type and based on the Lorentz force (of a known type, not described in detail here). In a possible implementation, this sensing structure is a MEMS (Micro Electro Mechanical System) structure.

According to an aspect of the present solution, this sensor die 31 is arranged on and in contact with the first conductive strip 24b and, in the illustrated example, the second conductive strip 24c. The sensor die 31 has a rectangular or square shape in the horizontal plane xy and in particular has an extension along the horizontal axis x greater than the sum of the respective extensions of the first and second conductive strips 24b, 24c and the corresponding separation distance along the same horizontal axis x.

Furthermore, the power device 1 comprises a contact element 34, made of a conductive material, for example copper, arranged above the aforementioned source metallization 24.

In particular, this contact element 34 is configured and shaped so as to electrically connect the first and the second conductive strips 24b, 24c to the main portion 24a of the source metallization 24, so that they are at a same electrical potential (corresponding to that of the source terminal).

In detail, this contact element 34 comprises a main portion 34a, having a rectangular or square extension in the horizontal plane xy, arranged on and in contact with the main portion 24a of the source metallization 24, defining a homogeneous electrical contact throughout its extension, therefore relative to most of the active cells 11 of the integrated power structure.

The contact element 34 further comprises: a first bridge portion 34b (shown in the cross-section of FIG. 2A), having a cantilever extension, in the example along the horizontal axis x, starting from the main portion 34a of the same contact element 34, towards the first conductive strip 24b (therefore extending above the second conductive strip 24c, at a certain separation distance along the vertical axis z); and a first connecting portion 36 (shown schematically in FIG. 1 and illustrated in FIG. 2A), which extends vertically from the aforementioned first bridge portion 34b (in particular from one distal end thereof with respect to the main portion 34a) along the vertical axis z up to, and contacting in a localized manner, an end portion of the aforementioned first conductive strip 24b.

In particular, this first connecting portion 36 has, in the horizontal plane xy, a substantially square (or circular) cross-section, with an extension in the same horizontal plane xy that is much smaller with respect to the extension of the aforementioned first conductive strip 24b (this cross-section is also contained within the same first conductive strip 24b).

The contact element 34 further comprises: a second bridge portion 34c (shown in FIG. 2C), also having a cantilever extension along the horizontal axis x, starting from the main portion 34a of the same conductive element 34, above the first conductive strip 24b (at a certain separation distance along the vertical axis z) and the second conductive strip 24c; and a second connecting portion 37 (shown schematically in FIG. 1 and illustrated in FIG. 2C), which extends vertically from the aforementioned second bridge portion 34c (in particular starting from a central portion thereof) along the vertical axis z up to, and contacting in a localized manner, a respective end portion of the aforementioned second conductive strip 24c (in particular, arranged on an opposite side along the y axis with respect to the aforementioned end portion of the first conductive strip 24b). Furthermore, the first and second connecting portions 36, 37 are staggered or offset along the horizontal axis x, being arranged at the first and, respectively, at the second conductive strip 24b, 24c.

As it is evident from FIG. 1, the aforementioned bridge portions 34b, 34c define therebetween, in the horizontal plane xy, in particular along the horizontal axis y, a window 38; the aforementioned current sensor 30 is arranged at and within this window 38.

As shown schematically in FIG. 1, the aforementioned contact element 34 electrically contacts the electrical contact terminals 5 of one of the two parallel rows (in the example, of the first row and the corresponding terminals indicated by references 1 to 9), which define together (being short-circuited to each other) the source terminal of the MOSFET structure, for the external electronic system.

As shown in FIG. 1 and in the cross-section of FIG. 2C, in the same layer where the aforementioned source metallization 24 is defined, a gate contact pad 40 is also formed, which contacts, in a manner not illustrated in detail, the gate regions 20 of the active cells 11 of the MOSFET transistor.

Furthermore, as shown in FIG. 1 and in the cross-sections of FIGS. 2B and 2C, the power device 1 comprises a circuit die 42, of semiconductor material, for example silicon, which integrates an ASIC (Application Specific Integrated Circuit) electronic circuit, operatively and electrically coupled to the power die 10 (in the example, to the corresponding MOSFET transistor) and to the sensor die 31.

In particular, the circuit die 42 is arranged on the main portion 34a of the contact element 34 (in the example centrally with respect to the horizontal plane xy), being coupled thereto by a thin layer of insulating material 43 (for example a non-conductive double-sided adhesive material).

In detail, as shown schematically in the aforementioned FIGS. 1 and 2B, first bonding wires 44 electrically connect the circuit die 42 (in particular, corresponding contact pads carried by an upper surface, opposite to the surface for bonding to the contact element 34) to the sensor die 31 (in particular, to respective contact pads carried by a respective upper surface, opposite to the surface for bonding to the first and the second conductive strips 24b, 24c). In the illustrated embodiment, the aforementioned first bonding wires 44 are arranged, in part, within the window 38.

Furthermore, as shown in FIG. 2C, at least a second bonding wire 45 electrically connects the circuit die 42 to the gate contact pad 40.

As shown in FIG. 1, third bonding wires 46 electrically connect the circuit die 42 to respective electrical contact terminals 5, in the example of the second one of the two parallel rows (in particular, in the example, with the terminals indicated by references 16 to 18), which define input/output terminals of the power device 1 with respect to the external electronic system.

As previously mentioned, the various elements forming the power device 1 (including in particular, the power die 10, the source metallization 24, the sensor die 31, the contact element 34, the circuit die 42 and the first, second and third bonding wires 44, 45, 46) are encased within the external coating 4 of the package 2.

In greater detail, and also referring to the circuit diagram of FIG. 4, the aforementioned ASIC electronic circuit integrated into the circuit die 42 comprises a driving stage 50, operatively coupled to the power die 10 and configured to provide a driving signal S_{d} for the gate regions 20 of the power structure integrated in the same power die 10, through the gate contact pad 40. The driving stage 50 is also connected to at least one of the aforementioned input/output terminals of the electrical contact terminals 5, in particular to receive a gate biasing signal V_{g} from the external electronic system, as a function of which the aforementioned driving signal S_{d} is generated.

The same ASIC electronic circuit further comprises a sensing stage 52, operatively coupled to the sensor die 31 of the current sensor 30 and configured to provide suitable biasing signals to the magnetic field sensing structure integrated into the sensor die 31 and also to receive at least a current sensing signal Sᵢ from the same sensing structure. The sensing stage 52 is further connected to at least one of the aforementioned input/output terminals of the electrical contact terminals 5, in particular to provide an output signal Sₒᵤₜ, indicative of the sensing current (and, therefore, of the load electric current).

FIG. 4 also shows an equivalent circuit diagram of the power structure integrated into the power die 10, in the example of the MOSFET transistor previously referred to.

In particular, a transistor M1, having a drain connected to a power supply terminal (defined by the drain contact terminal) and receiving a power supply voltage Vₐ₁ and a gate terminal connected to the aforementioned driving stage 50 to receive the driving signal S_{d}, represents the at least one active cell 11 of the MOSFET transistor coupled to the first conductive strip 24b.

Similarly, the transistor M2, having a drain connected to the power supply terminal and a gate terminal connected to the aforementioned driving stage 50 to receive the driving signal S_{d}, represents the at least one respective and distinct active cell 11 of the MOSFET transistor coupled to the second conductive strip 24c.

The transistor M3, having a drain connected to the power supply terminal, a gate terminal connected to the aforementioned driving stage 50 to receive the same driving signal S_{d} and a source terminal connected to the source contact terminal, represents the parallel of the remaining most part of the active cells 11 of the power device 1, arranged at the main portion 24a of the source metallization.

In the same FIG. 4, the first and the second current paths defined by the first and the second conductive strips 24b, 24c are also schematically represented, with the current sensor 30, formed in the corresponding sensor die 31, which is arranged at the same first and second conductive strips 24b, 24c.

During operation of the power device 1, the aforementioned active cells 11 of the power structure are configured to generate, after suitable electrical biasing by the driving stage 50, the load electric current, indicated here by I_{load}, which is supplied to an external electronic component, acting as a load.

This load current I_{load}, within the power die 10, in most of the active cells 11 (represented by the aforementioned transistor M3) flows from the conductive layer 27, which forms the drain contact terminal, towards the source metallization 24, uniformly contacted by the contact element 34, which defines the source contact terminal.

Furthermore, within the same power die 10, at least one path is defined for a first sensing current, here indicated by Iᵣ₁, which, in at least one active cell 11 of the MOSFET transistor (represented by the aforementioned transistor M1), flows from the conductive layer 27, i.e., from the drain contact terminal, towards the first conductive strip 24b, and then flows, in a first direction along the y axis indicated by the corresponding arrow in FIG. 1 and in FIG. 4, towards the source contact terminal through the first bridge portion 34b of the contact element 34.

This first sensing current Iᵣ₁ therefore contributes to the generation of the aforementioned load electric current I_{load}, being part thereof, according to a proportionality ratio substantially defined by the area ratio (in the horizontal plane xy) between the first conductive strip 24b and the main portion 24a of the source metallization 24 (this ratio being for example comprised in the range between 10% and 25%).

Furthermore, this first sensing current Iᵣ₁ generates a magnetic flux which may be sensed by the current sensor 30, for the generation of the aforementioned current sensing signal Sᵢ.

As discussed previously, within the same power die 10, a path of a second sensing current, here indicated by Iᵣ₂, may be defined, which, in at least one respective active cell 11 of the MOSFET transistor (represented by the aforementioned transistor M2), flows from the conductive layer 27, i.e., from the drain contact terminal, towards the second conductive strip 24c, and then flows, in a second direction along the y axis indicated by the corresponding arrow in FIG. 1 and in FIG. 4 (which is opposite with respect to the first direction of the first sensing current Iᵣ₁), towards the source contact terminal through the second bridge portion 34c of the contact element 34.

Therefore, also this second sensing current Iᵣ₂ contributes to generation of the aforementioned load electric current I_{load}, being part thereof, according to a proportionality ratio substantially defined by the area ratio (in the horizontal plane xy) between the second conductive strip 24c and the main portion 24a of the source metallization 24 (for example, in the same range previously indicated).

This second sensing current Iᵣ₂ generates a respective magnetic flux which is sensed by the current sensor 30, contributing to the generation of the current sensing signal Sᵢ.

Advantageously, the aforementioned sensing stage 52 integrated into the circuit die 42 may implement a differential sensing scheme, based on the magnetic fluxes generated by the first and the second sensing currents Iᵣ₁, Iᵣ₂, having opposite directions, so as to eliminate, in the generation of the output signal Sₒᵤₜ, the contribution due to any external magnetic fields or interferences.

The advantages of the proposed solution are clear from the preceding disclosure.

In any case, it is emphasized that this solution allows to measure and/or monitor an electric current in an analog power application in a very wide range of frequencies, from D.C. up to several MHz.

Furthermore, the described solution allows an electric current sensor integrated into a semiconductor power device to be manufactured in an extremely small volume, within a package of an integrated system, with a much lower area occupation compared to traditional measuring solutions (using discrete components, such as resistors, transistors or Hall-effect sensors, external and separate with respect to the semiconductor power device).

In a similar manner, the present solution allows a semiconductor power device to be manufactured with an integrated functionality for monitoring a current (in particular, an electric current supplied to a corresponding load).

Finally, it is clear that modifications and variations may be made to what has been described and illustrated herein without thereby departing from the scope of the present disclosure, as defined in the attached claims.

In particular, it is highlighted that the arrangement of the sensing current paths (defined by the aforementioned first and second conductive strips 24b, 24c) might be different within the package 2 of the power device 1, for example being able to be aligned parallel to the horizontal axis x.

Moreover, it is underlined that the ASIC electronic circuit integrated into the circuit die 42 might have further functionalities in addition to monitoring the electric current and driving the integrated power structure.

A semiconductor power device (1), may be summarized as including: a package (2); a power die (10), arranged within the package (2) and integrating a power structure configured to generate a load electric current (I_{load}) designed to be supplied to an electric load, characterized by including, within the package (2): at least a first conductive path (24b) configured to be flown through by a first sensing current (Iᵣ₁), which is a function of said load electric current (I_{load}); and a current sensor (30) with magnetic-based operation, integrated into a sensor die (31) coupled to said first conductive path (24b) and configured to generate a current sensing signal (Sᵢ), based on said first sensing current (Iᵣ₁).

Said package (2) may have at least one input/output electrical contact terminal (5) with respect to an external environment; may further include, within the package (2), a circuit die (42) integrating an electronic circuit, may include a sensing stage (52), operatively coupled to said current sensor (30) and configured to receive said current sensing signal (Sᵢ) and output, on said at least one input/output terminal of said package (2), an output signal (Sₒᵤₜ), indicative of the load electric current (I_{load}).

Said package (2) may have at least one further input/output electrical contact terminal (5) with respect to the external environment; and the electronic circuit integrated into said circuit die (42) may further include a driving stage (50) operatively coupled to the power structure in the power die (10) and configured to provide a driving signal (S_{d}) for said integrated power structure, as a function of a biasing signal (V_{g}) at said at least one further input/output terminal of said package (2).

The device may further include, within said package (2): a second conductive path (24c), arranged parallel to said first conductive path (24b) and to an extension axis (y) and designed to be flown through by a second sensing current (Iᵣ₂), which is a function of said load electric current (I_{load}), in an opposite direction along said extension axis (y) with respect to a respective direction of said first sensing current (Iᵣ₁); wherein said current sensor (30) may be further coupled to said second conductive path (24c) for the generation of said current sensing signal (Sᵢ) also based on said second sensing current (Iᵣ₂).

The device may include, within the package (2): a conductive layer (24), arranged above the power die (10) and configured to define a current conduction terminal for said power structure, said conductive layer (24) may include a main portion (24a) and at least a first conductive strip (24b), separate and distinct with respect to the main portion (24a) and defining said first conductive path; and furthermore a contact element (34), of conductive material, arranged above said conductive layer (24) and configured to electrically connect said first conductive strip (24b) to said main portion (24a), so that they are at a same electrical potential.

Said package (2) may have at least one electrical contact terminal (5) at which said load electric current (I_{load}) is present; wherein said contact element (34) may be electrically coupled to said at least one electrical contact terminal (5).

Said sensor die (31) may be arranged on and in contact with said first conductive strip (24b).

Said contact element (34) may include: a main portion (34a), having a main extension in a horizontal plane (xy) and arranged on and in contact with the main portion (24a) of the conductive layer (24), defining a uniform electrical contact throughout the main extension thereof; and a first bridge portion (34b), having a cantilever extension from the main portion (34a) above the power die (10) and provided with a first connecting portion (36), which extends vertically to said horizontal plane (xy) from a distal end of said first bridge portion (34b) with respect to the main portion (34a), to contact, in a localized manner, a first end portion of said first conductive strip (24b).

Said first conductive strip (24b) may have a main extension along an extension axis (y) of said horizontal plane (xy) and said first sensing current (Iᵣ₁) may be designed to flow along said first conductive strip (24b) in a first direction of said extension axis (y), from a second end portion of said first conductive strip (24b), opposite to said first end with respect to said extension axis (y), towards said first end portion, and to flow into said contact element (34) through said first connecting portion (36) and said first bridge portion (34b).

Said conductive layer (24) may further include a second conductive strip (24c), separate and distinct with respect to the main portion (24a) and with respect to said first conductive strip (24b) and defining a second conductive path arranged parallel to the first conductive path and to said extension axis (y) and designed to be flown through by a second sensing current (Iᵣ₂), which is a function of said load electric current (I_{load}), in a second direction along said extension axis (y) opposite with respect to the first direction of said first sensing current (Iᵣ₁); and said contact element (34) may include a second bridge portion (34c), having a cantilever extension from the main portion (34a) above the power die (10) and provided with a second connecting portion (37), which extends vertically to said horizontal plane (xy) from said second bridge portion (34b) to contact, in a localized manner, a respective first end portion of said second conductive strip (24c), opposite to the first end portion of said first conductive strip (24b) with respect to said extension axis (y).

Said second sensing current (Iᵣ₂) may be designed to flow along said second conductive strip (24c) in said second direction, from a respective second end portion of said second conductive strip (24c), opposite to said respective first end with respect to said extension axis (y), towards said respective first end portion, and to flow into said contact element (34) through said second connecting portion (37) and said second bridge portion (34c).

Said first and second bridge portions (34b, 34c) may define therebetween, along said extension axis (y), a window (38), wherein said sensor die (31) of said current sensor (30) is arranged.

The device may further include, within the package (2), a circuit die (42) integrating an electronic circuit, may include a sensing stage (52), operatively coupled to said current sensor (30); wherein said circuit die (42) may be arranged above said main portion (34a) of said contact element (34) and may be electrically connected to said sensor die (31) of said current sensor (30) by bonding wires (44).

Said power structure integrated into said power die (10) may define a power transistor and said conductive layer (24) may define a first current conduction terminal of said power transistor; said power structure may further include, at a surface of said power die (10) opposite along said vertical axis (z) to a surface for bonding to said conductive layer (24), a further conductive layer (27), which may define a second current conduction terminal of the power transistor; wherein said load electric current (I_{load}) may be designed to flow between said second current conduction terminal and said first current conduction terminal.

Said power transistor may be of the MOSFET type and may include a plurality of cells (11) each having respective source regions (18); and: source regions (18) of at least one of said cells (11) may be electrically coupled to said first conductive strip (24b); and source regions (18) of remaining ones of said cells (11) may be electrically coupled to said main portion (24a) of said conductive layer (24), which may be a source metallization for said power transistor.

Said current sensor (30) may include a magnetometer, based on the magnetoresistance principle.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor power device, comprising:
a package;
a power die, arranged within the package and integrating a power structure configured to generate a load electric current configured to be supplied to an electric load,
wherein the package includes:
at least a first conductive path configured to have a first sensing current pass therethrough, wherein the first sensing current is a function of said load electric current; and
a current sensor, integrated into a sensor die coupled to said first conductive path and configured to generate a current sensing signal, based on said first sensing current.

2. The device according to claim 1, further comprising, within the package, a circuit die integrating an electronic circuit, the circuit die including a sensing stage, operatively coupled to said current sensor;
wherein said package has at least one input/output electrical contact terminal with respect to an external environment; and
wherein the sensing stage is configured to receive said current sensing signal and output, on said at least one input/output terminal of said package, an output signal, indicative of the load electric current.

3. The device according to claim 2, wherein said package has at least one further input/output electrical contact terminal with respect to the external environment;
wherein the electronic circuit integrated into said circuit die further includes a driving stage operatively coupled to the power structure in the power die; and
wherein the driving stage is configured to provide a driving signal for said integrated power structure, as a function of a biasing signal at said at least one further input/output terminal of said package.

4. The device according to claim 1, further comprising, within said package:
a second conductive path, arranged parallel to said first conductive path and to an extension axis and configured to be flown through by a second sensing current, which is a function of said load electric current, in an opposite direction along said extension axis with respect to a respective direction of said first sensing current;
wherein said current sensor is further coupled to said second conductive path for the generation of said current sensing signal; and
wherein said current sensing signal is further based on said second sensing current.

5. The device according to claim 1, comprising, within the package:
a conductive layer, arranged above the power die and configured to define a current conduction terminal for said power structure; and
a contact element, of conductive material, arranged above said conductive layer;
wherein said conductive layer includes a main portion and at least a first conductive strip, separate and distinct with respect to the main portion and defining said first conductive path; and
wherein the contact element is configured to electrically connect said first conductive strip to said main portion and have both said first conductive strip and said main portion at a same electrical potential.

6. The device according to claim 5, wherein said package has at least one electrical contact terminal at which said load electric current is present; and
wherein said contact element is electrically coupled to said at least one electrical contact terminal.

7. The device according to claim 5, wherein said sensor die is arranged on and in contact with said first conductive strip.

8. The device according to claim 5, wherein said contact element comprises:
a main portion, having a main extension in a horizontal plane and arranged on and in contact with the main portion of the conductive layer, defining a uniform electrical contact throughout the main extension thereof; and
a first bridge portion, having a cantilever extension from the main portion above the power die and provided with a first connecting portion, which extends vertically to said horizontal plane from a distal end of said first bridge portion with respect to the main portion, to contact, in a localized manner, a first end portion of said first conductive strip.

9. The device according to claim 8, wherein said first conductive strip has a main extension along an extension axis of said horizontal plane and said first sensing current is configured to flow along said first conductive strip in a first direction of said extension axis, from a second end portion of said first conductive strip, opposite to said first end with respect to said extension axis, towards said first end portion, and to flow into said contact element through said first connecting portion and said first bridge portion.

10. The device according to claim 9, wherein said conductive layer further comprises:
a second conductive strip, separate and distinct with respect to the main portion and with respect to said first conductive strip and defining a second conductive path arranged parallel to the first conductive path and to said extension axis and configured to have a second sensing current pass therethrough, which is a function of said load electric current, in a second direction along said extension axis opposite with respect to the first direction of said first sensing current; and
wherein said contact element comprises a second bridge portion, having a cantilever extension from the main portion above the power die and provided with a second connecting portion, which extends vertically to said horizontal plane from said second bridge portion to contact, in a localized manner, a respective first end portion of said second conductive strip, opposite to the first end portion of said first conductive strip with respect to said extension axis.

11. The device according to claim 10, wherein said second sensing current is configured to flow along said second conductive strip in said second direction, from a respective second end portion of said second conductive strip, opposite to said respective first end with respect to said extension axis, towards said respective first end portion, and to flow into said contact element through said second connecting portion and said second bridge portion.

12. The device according to claim 10, wherein said first and second bridge portions define therebetween, along said extension axis, a window, wherein said sensor die of said current sensor is arranged.

13. The device according to claim 5, further comprising, within the package, a circuit die integrating an electronic circuit, comprising a sensing stage, operatively coupled to said current sensor; wherein said circuit die is arranged above said main portion of said contact element and is electrically connected to said sensor die of said current sensor by bonding wires.

14. The device according to claim 5, wherein said power structure integrated into said power die defines a power transistor and said conductive layer defines a first current conduction terminal of said power transistor; said power structure further comprising, at a surface of said power die opposite along said vertical axis to a surface for bonding to said conductive layer, a further conductive layer, which defines a second current conduction terminal of the power transistor; wherein said load electric current is configured to flow between said second current conduction terminal and said first current conduction terminal.

15. The device according to claim 14, wherein said power transistor is of a MOSFET type and comprises a plurality of cells each having respective source regions; and wherein: source regions of at least one of said cells are electrically coupled to said first conductive strip; and source regions of remaining ones of said cells are electrically coupled to said main portion of said conductive layer, which is a source metallization for said power transistor.

16. The device according to claim 1, wherein said current sensor comprises a magnetometer, based on the magnetoresistance principle.

17. A semiconductor package, comprising:
a power die integrating a power structure configured to generate a load electric current to be supplied to an electric load,
at least a first conductive path configured to have a first sensing current pass therethrough, the first sensing current beings a function of said load electric current;
a senor die;
a current sensor integrated into the sensor die coupled to said first conductive path, the current sensor configured to generate a current sensing signal, based on said first sensing current.

18. The semiconductor package according to claim 17, further comprising:
a second conductive path, arranged adjacent to said first conductive path and to an extension axis and configured to have a second sensing current pass therethrough, which is a function of said load electric current, in an opposite direction along said extension axis with respect to a respective direction of said first sensing current;
wherein said current sensor is further coupled to said second conductive path for the generation of said current sensing signal; and
wherein said current sensing signal is based on said second sensing current.

19. The semiconductor package according to claim 17, further comprising:
a circuit die integrating an electronic circuit, the circuit die including a sensing stage, operatively coupled to said current sensor; and
at least one input/output electrical contact terminal with respect to an external environment;
wherein the sensing stage is configured to receive said current sensing signal and output, on said at least one input/output terminal of said package, an output signal, indicative of the load electric current.

20. The semiconductor package according to claim 19, further comprising:
at least one further input/output electrical contact terminal with respect to the external environment;
wherein the electronic circuit integrated into said circuit die further includes a driving stage operatively coupled to the power structure in the power die; and
wherein the driving stage is configured to provide a driving signal for said integrated power structure, as a function of a biasing signal at said at least one further input/output terminal of said package.
